(19) United States
(12) Patent Application Publication
(10) Pub. No.: US 2026/0319018 A1
(43) Pub. Date: Oct. 15, 2026

(54) Short Circuit Detection In Current Sensors

(71) Applicant: Allegro MicroSystems, LLC, Manchester, NH (US)

(72) Inventors: Pablo Jesús Gardella, Heidelberg (DE); Eduardo Mariani, Ciudad Autónoma de Buenos Aires (AR); Alexander Latham, Harvard, MA (US)

(73) Assignee: Allegro MicroSystems, LLC, Manchester, NH (US)

(21) Appl. No.: 19/177,941

(22) Filed: Apr. 14, 2025

(51) Int. Cl. G01R 31/52; G01R 15/18; G01R 15/20; G01R 19/00

(52) U.S. Cl. CPC G01R 31/52; G01R 15/18; G01R 15/202; G01R 19/0092

(57) ABSTRACT

A current sensor, comprising: a short circuit sensing circuit that is configured to detect increases in a level of electrical current through a conductor, the short circuit sensing circuit including at least one sensing element, a rectifier, and a detector, the sensing element being configured to generate a signal in response to a magnetic field that is generated by the conductor as a result of electrical current flowing through the conductor, the rectifier being configured to rectify the signal to produce a rectified signal, and the detector being configured to compare a characteristic of the rectified signal to a threshold and generate, at least in part, an output signal that is indicative of a presence of a short circuit when the characteristic of the rectified signal exceeds the threshold.

### BACKGROUND

As is known, sensors are used to perform various functions in a variety of applications. Some sensors include one or more magnetic field sensing elements, such as a Hall effect element or a magnetoresistive element, to sense a magnetic field associated with proximity or motion of a target object, such as a ferromagnetic object in the form of a gear or ring magnet, or to sense a current, as examples. Sensor integrated circuits are widely used in automobile control systems and other safety-critical applications. There are a variety of specifications that set forth requirements related to permissible sensor quality levels, failure rates, and overall functional safety.

### SUMMARY

According to aspects of the disclosure, a current sensor is provided, comprising: a current sensing circuit that is configured to detect a level of electrical current through a conductor, the current sensing circuit including at least one first magnetic field sensing element and a processing circuitry, the first sensing magnetic field sensing element being configured to generate a first signal in response to a magnetic field that is generated by the conductor as a result of electrical current flowing through the conductor, the processing circuitry being configured to generate a first output signal based on the first signal, the first output signal being indicative of a level of electrical current through the conductor; and a short circuit sensing circuit that is configured to detect increases in the level of electrical current that is flowing through the conductor, the short circuit sensing circuit including at least one second sensing element, a rectifier, and a detector, the second sensing element being configured to generate a second signal in response to the magnetic field that is generated by the conductor as a result of electrical current flowing through the conductor, the rectifier being configured to rectify the second signal to produce a rectified signal, and the detector being configured to compare a characteristic of the rectified signal to a threshold and generate, at least in part, an output signal that is indicative of a presence of a short circuit when the characteristic of the rectified signal exceeds the threshold.

According to aspects of the disclosure, a current sensor is provided, comprising: a current sensing circuit that is configured to detect a level of electrical current through a conductor, the current sensing circuit including at least one first magnetic field sensing element and a processing circuitry, the first sensing magnetic field sensing element being configured to generate a first signal in response to a magnetic field that is generated by the conductor as a result of electrical current flowing through the conductor, the processing circuitry being configured to generate a first output signal based on the first signal, the first output signal being indicative of a level of electrical current through the conductor; and a short circuit sensing circuit that is configured to detect increases in the level of electrical current that is flowing through the conductor, the short circuit sensing circuit including at least one second sensing element, an attenuator, and a detector, the second sensing element being configured to generate a second signal in response to the magnetic field that is generated by the conductor as a result of electrical current flowing through the conductor, the attenuator being configured to attenuate the second signal before the second signal is provided to the detector, and the detector being configured to compare a characteristic of the second signal to a threshold and generate, at least in part, an output signal that is indicative of a presence of a short circuit when the characteristic of the second signal exceeds the threshold.

According to aspects of the disclosure, a current sensor is provided, comprising: a current sensing circuit that is configured to detect a level of electrical current through a conductor, the current sensing circuit including at least one first magnetic field sensing element and a processing circuitry, the first sensing magnetic field sensing element being configured to generate a first signal in response to a magnetic field that is generated by the conductor as a result of electrical current flowing through the conductor, the processing circuitry being configured to generate a first output signal based on the first signal, the first output signal being indicative of a level of electrical current through the conductor; and a short circuit sensing circuit that is configured to detect increases in the level of electrical current that is flowing through the conductor, the short circuit sensing circuit including at least one second sensing element, a rectifier, and a detector, the second sensing element being configured to generate a second signal in response to the magnetic field that is generated by the conductor as a result of electrical current flowing through the conductor, the rectifier being configured to rectify the second signal to produce a rectified signal, and the detector being configured to integrate the rectified signal over a predetermined time period to produce an integrated signal, compare the integrated signal to a threshold, and generate, at least in part, an output signal that is indicative of a presence of a short circuit when the integrated signal exceeds the threshold.

### BRIEF DESCRIPTION OF THE DRAWINGS

The foregoing features may be more fully understood from the following description of the drawings in which:

FIG. 1 is a diagram of an example of a system, according to aspects of the disclosure;

FIG. 2 is a diagram of an example of a system, according to aspects of the disclosure;

FIG. 3 is a diagram of an example of a rectifier, according to aspects of the disclosure;

FIG. 4 is a diagram of an example of a lookup table, according to aspects of the disclosure;

FIG. 5 is a diagram of an example of a profile, according to aspects of the disclosure;

FIG. 6 is a diagram of an example of a lookup table, according to aspects of the disclosure; and

FIG. 7 is a flowchart of an example of a process, according to aspects of the disclosure.

### DETAILED DESCRIPTION

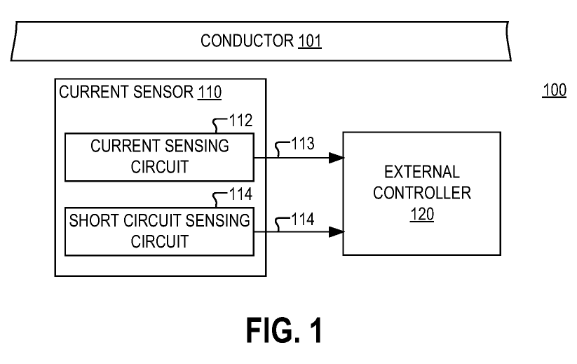

FIG. 1 illustrates an example of a system 100, according to aspects of the disclosure. As shown, system 100 may include a conductor 101, a current sensor 110, and an external controller 120. External controller 120 may include any suitable type electronic circuitry, such as an electronic control unit (ECU), a computer, and/or any other similar device. External controller 120 may use the outputs of current sensor 110 in control an electric vehicle (or portion of), machinery, and/or any other suitable type of machine or device.

The current sensor 110 may be positioned adjacent to conductor 101 and arranged to measure the level of electrical current flowing through it. Specifically, current sensor 110 includes a current sensing circuit 112 (hereinafter “circuit 112”) and a short circuit sensing circuit 114 (hereinafter “circuit 114”). Circuit 112 is configured to measure the electrical current through conductor 101 and report these measurements to external controller 120 by generating a signal 113 that indicates the current level. Circuit 114 is designed to detect increases in electrical current, which may signify a short circuit in the electrical system of which conductor 101 is a part. In this case, circuit 114 generates a signal 115 that indicates whether a short circuit has occurred and provides this signal to external controller 120.

One possible application of system 100 is in industrial control systems that operate machinery such as hydraulic presses, lathes, milling machines, or injection molding machines. In these examples, conductor 101 carries the electrical current needed to power the machinery and extends between a power source to the machinery itself. External controller 120 can operate the machinery based on signals 113 and 115. For instance, when signal 115 indicates a short circuit, external controller 120 may shut down or disconnect the power source from the machinery or take other preventive measures to avoid damage.

Another possible application of system 100 is in electric vehicles. In this scenario, conductor 101 may couple a battery (or another power source) to an electric motor of the vehicle and carry the electrical current to power the motor. Here, external controller 120 would operate the motor based on signals 113 and 115. If signal 115 indicates a short circuit, external controller 120 may disconnect the battery from the motor or implement other safety measures to prevent damage.

The present disclosure is not limited to specific applications of system 100. In general, system 100 can be used to detect short circuits in any electrical system.

A brief discussion is now provided of one possible use of sensor 110, which has a dedicated circuit (i.e., circuit 114) for detecting short circuits. As is widely known, a short circuit occurs when an unintended low-resistance path is created between two points in an electrical circuit, allowing excessive current to flow. This can lead to fires, equipment damage, and other undesirable consequences. In systems that carry substantial electrical current, a short circuit can result in a dramatic current surge. For instance, a current of 400A can develop in as little as 80 nanoseconds. Such a rapid increase can be undetectable by conventional current sensing circuits, like circuit 112, due to the high rate of change and the magnitude of the electrical current. Therefore, sensor 110 employs circuit 114, a dedicated circuit tailored for detecting short circuit events. Circuit 114 is adapted to sense high-frequency signals and is equipped to handle high levels of current.

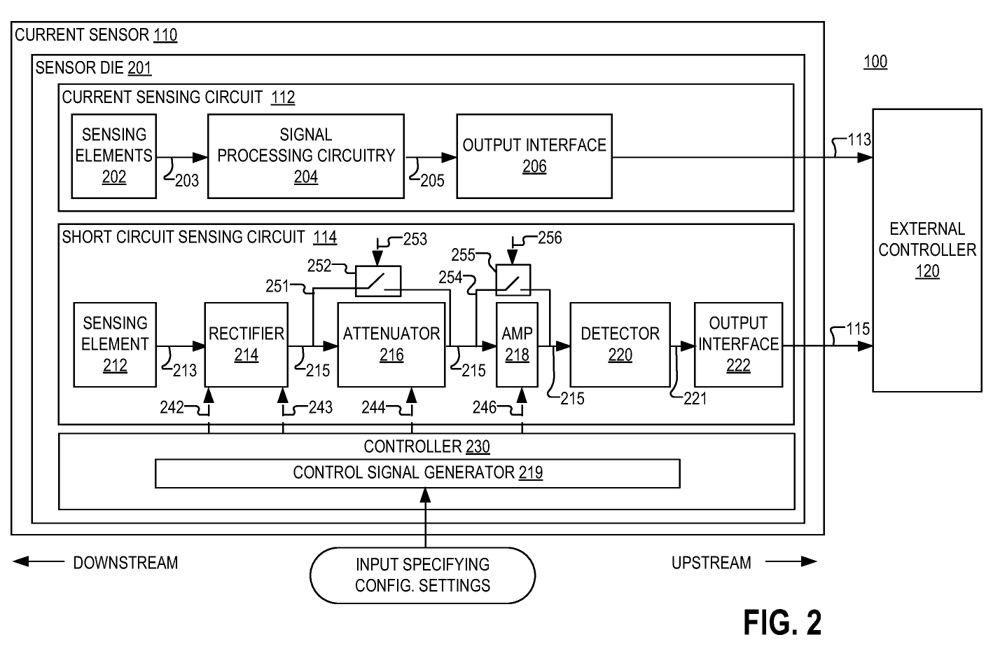

FIG. 2 is a schematic diagram of system 100, illustrating a specific implementation. In this example, sensor 110 includes a sensor die 201, circuits 112 and 114, and a controller 230.

Sensor die 201 can include a silicon substrate or any other suitable substrate commonly used in the manufacturing of integrated circuits. Circuits 112 and 114, and controller 230 can all be formed on the sensor die 201.

Controller 230 can include a general-purpose processor, a special-purpose processor, a digital logic circuit, or any other suitable type of processing circuitry. In some cases, controller 230 may be configured to receive input for one or more configuration settings and to reconfigure circuit 114 accordingly. In certain implementations, controller 230 may perform the process 700 discussed later in relation to FIG. 7.

An example of a possible configuration for circuit 112 is now provided. As illustrated, circuit 112 may include a sensing element 202, signal processing circuitry 204, and an output interface 206. The sensing element 202 may include one or more magnetic field sensing elements. In this example, sensing elements 202 comprise one or more Hall elements (such as planar or vertical Hall elements). However, alternative implementations may include sensing elements 202 that include giant magnetoresistance (GMR) elements, tunneling magnetoresistance (TMR) elements, inductive coils, or other suitable types of magnetic field sensing elements. Signal processing circuitry 204 may include any appropriate digital and/or analog circuitry typically found in current sensors. For example, it may include one or more amplifiers, digital-to-analog converters (DACs), analog-to-digital converters (ADCs), filters (either digital or analog), a signal processor, and offset adjustment circuitry designed to compensate for environmental effects (such as temperature) on the offset of sensing elements 202. Output interface 206 may include any suitable type of digital or analog output interface. For example, it could be a signal driver or any other appropriate interface for forwarding signals. The present disclosure is not limited to any specific configuration of circuit 112. Circuit 112 may have any suitable configuration that conventional current sensors are known to have by those of ordinary skill in the art.

An example of the operation of circuit 112 is now provided. In operation, sensing elements 202 generate a signal 203 and send this signal to signal processing circuitry 204. Signal 203 is produced in response to a magnetic field generated by conductor 101 (as shown in FIG. 1), resulting from electrical current flowing through conductor 101. This signal 203 indicates the level of electrical current flowing through the conductor. Signal processing circuitry 204 processes signal 203 to generate a signal 205, which is then sent to output interface 206. Output interface 206 creates signal 113 based on signal 205 and forwards it to external controller 120. As noted earlier, signal 113 can include any suitable type of signal that is indicative of the level of electrical current flowing through conductor 101.

An example of a possible configuration for circuit 114 is now discussed. Circuit 114 may comprise one or more sensing elements 212, a rectifier 214, an attenuator 216, an amplifier 218, a detector 220, and an output interface 222. In this example, sensing element 212 includes an inductive coil. While sensing element 212 is formed on sensor die 201 in the current example, alternative implementations may allow for sensing element 212 to be provided separately from sensor 110. In such instances, sensing element 212 could connect to rectifier 214 through one or more input terminals (not shown) of sensor 110. It is important to note that while the present example uses an inductive coil for sensing element 212, the disclosure is not limited to this configuration. Sensing element 212 may also include GMR elements, TMR elements, and/or any other suitable type of magnetic field sensing element

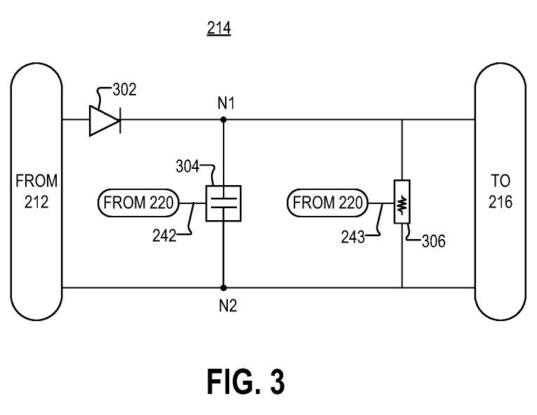

Rectifier 214 may include any suitable type of rectifier. An example of a possible implementation of rectifier 214 is shown in FIG. 3. As illustrated in FIG. 3, the rectifier may include a diode 302, a capacitor 304, and a resistor 306. Diode 302 functions as a rectifier, allowing current to flow only from sensing element 212 to attenuator 216. Capacitor 304 smooths the output of diode 302 by charging when voltage is available and discharging during periods when the voltage from diode 302 diminishes. Resistor 306 aids in the gradual discharge of the capacitor and ensures a continuous current flow through rectifier 214.

In some implementations, capacitor 304 may be an adjustable capacitor, and/or resistor 306 may be an adjustable resistor. The capacitance of capacitor 304 can be set by a signal 242 provided to the circuit 114 by controller 230. Capacitor 304 can be implemented as a varicap or any suitable device or circuit configured to offer adjustable capacitance. Similarly, the resistance of resistor 306 can be adjusted by a signal 243 supplied to circuit 114 by controller 230. Signals 242 and 243 may be utilized to configure the timing constant of capacitor 304. Resistor 306 may be implemented as a digital potentiometer or any other suitable device that provides adjustable resistance.

As noted above, the capacitance of capacitor 304 can be adjusted based on signal 242 from controller 230. Additionally, the resistance of resistor 306 can be adjusted using signal 243 from controller 230. This capability allows controller 230 to control the timing constant of rectifier 214, which, in this particular example, is determined by the product of the capacitance of capacitor 304 and the resistance of resistor 306. This timing constant dictates how quickly circuit 114 responds to changes in voltage across conductor 101. Being able to set the timing constant of rectifier 214 is advantageous because it allows circuit 114 to be tailored for different dI/dt profiles—essentially, it enables sensors 110 to be customized to work with different rates of change of electrical current through conductor 101.

The rationale for variable timing constants in capacitor 304 is now explained further. Customizing the timing constant of capacitor 304 is advantageous as it allows circuit 114 to be adapted to many different applications. In high-current scenarios, significant current can rapidly develop in the event of a short circuit. Timely detection of increasing current levels during such events is crucial for effectively responding to the short circuit. The quicker the increase is detected, the better the chances are that the power supply can be turned off or disconnected before any damage occurs. Thus, the ability to set the timing constant ensures that rectifier 214 can respond quickly to an increase in current. For instance, if the current is expected to increase at a rate of 5 A/ns, the timing constant can be set to one value; if the current is expected to rise at a rate of 2 A/ns, a different timing constant can be applied. In other words, the ability set to set the timing constant enables customers who purchase sensor 110 to customize the operation of sensor 110 to their particular application.

Attenuator 216 may include one or more resistors configured to attenuate the output of rectifier 214. In some cases, attenuator 216 may function as a variable attenuator. The level of attenuation applied by attenuator 216 to the output of rectifier 214 is controlled by signal 244 from controller 230. In some implementations, attenuator 216 may also be implemented as a digital potentiometer or other devices that provide variable resistance. In the present example, attenuator 216 is disposed downstream from rectifier 214. However, alternative implementations are possible in which attenuator 216 is disposed upstream from rectifier 214 (e.g., between sensing element 212 and rectifier 214).

According to the present disclosure, attenuator 216 is considered "turned off" when it imparts no or negligible attenuation on the output of rectifier 214 or the sensing elements. For instance, attenuator 216 could be turned off by adjusting signal 244 to a value that causes attenuator 216 to apply minimal attenuation to the output of rectifier 214. Alternatively, attenuator 216 can be turned off by closing bypass line 251, allowing the output of rectifier 214 to travel to amplifier 218 directly without first passing through attenuator 216. Bypass line 251 may be closed by activating switch 252, which is controlled via a signal 253 generated by controller 230. For example, when signal 253 is set to '1', switch 252 closes, and when signal 253 is set to '0', switch 252 opens.

Amplifier 218 can be any type of amplifier designed to amplify the output from rectifier 214. In some cases, amplifier 218 may be a variable gain amplifier. The gain of amplifier 218 may be controlled by a signal (such as signal 246) that is provided to amplifier 218 by controller 230. According to the present disclosure, amplifier 218 is considered "turned off" when its gain is set to '1' or when it is bypassed using a bypass line. For instance, to turn off amplifier 218, signal 246 can be set to a value that adjusts the gain to 1 or close to it. Additionally or alternatively, in some implementations, amplifier 218 may operate with a closed bypass line 251, allowing the output of attenuator 216 to pass directly to detector 220 without going through amplifier 218 first. Bypass line 254 is closed by activating a switch, identified as switch 255. This switch is controlled by a signal (such as signal 256) that is generated by controller 230. For example, when signal 256 is set to '1', switch 255 will close, while setting signal 256 to '0' will open the switch.

The inclusion of attenuator 216 and amplifier 218 in circuit 114 serves a specific purpose. In some implementations, these components are utilized to ensure the output from rectifier 214 remains within predetermined limits suitable for processing by detector 220. In certain applications, the current level through conductor 101 can spike to 400A within 80 nanoseconds, resulting in a high magnetic flux density. Consequently, a significant voltage can be induced in sensing element 212. In such cases, it may be necessary to attenuate the output from rectifier 214 to protect detector 220 or for other reasons. Conversely, if the magnetic flux density from a short circuit is relatively low, it may induce a voltage in sensing element 212 that is below the sensitivity threshold of detector 220. If the output from rectifier 214 remains below this threshold, detector 220 will not trigger. Therefore, in these instances, amplifying the output from rectifier 214 may be beneficial.

It is important to note that if both attenuator 216 and amplifier 218 are activated simultaneously, they would counteract each other. Consequently, in some designs, only one of these components may be active at a time. Additionally, there may be implementations where at least one of attenuator 216 or amplifier 218 is omitted from sensor 110.

Detector 220 comprises electronic circuitry capable of performing several functions: (i) receiving the rectified output from sensing element 212 that may have been amplified or attenuated, (ii) comparing a characteristic of this output against a predetermined threshold, and (iii) generating an indication when the characteristic exceeds the threshold, signifying a detected short circuit. For example, the output characteristic could be amplitude, allowing detector 220 to be implemented as either a comparator or a Schmitt trigger. Alternatively, the output characteristic might be the rate of change of signal 215 over time or the summation of signal 215 over a certain time period. In such cases, detector 220 could incorporate an integrator and a comparator that triggers when the integrated signal value (over a specific time period) surpasses a threshold. Additionally, detector 220 may include digital circuitry that reports the actual signal level detected or other relevant information, such as rate of change of signal 215 (e.g., by dividing the integrated value over the period of integration, etc.). The present disclosure does not restrict the design of detector 220 to any specific implementation. Detector 220 may be implemented in the digital domain or in the analog domain.

Output interface 222 may include any suitable type of analog or digital interface. For example, output interface 222 may include an inter-integrated circuit (I2C) interface, a serial peripheral interface (SPI), a universal asynchronous receiver-transmitter (UART) interface, a signal driver, and/or any other suitable type of interface. In the example, of FIG. 2, each of circuits 112 and 114 is provided with a different output interface, however in some implementations, the same output interface (e.g., output interface 222) may be used to route the signals 113 and 115 to the external controller 120. Furthermore, this interface may be arranged to receive user input and provide the received user input to controller 230. It will be understood that the present disclosure is not limited to any specific configuration of the output interface of current sensor 110.

The operation of circuit 114 is now described in further detail. In operation, sensing element 212 may detect a magnetic field generated by the electrical current flowing through conductor 101. In response to this magnetic field, sensing element 212 may produce signal 213, which is then sent to rectifier 214. Rectifier 214 may rectify signal 213 to generate a rectified signal 215.

Optionally, attenuator 216 may reduce the strength of signal 215 and provide the attenuated version to detector 220 (as this example assumes that amplifier 218 is being bypassed). Detector 220 may compare a characteristic of signal 215 against a predetermined threshold to generate signal 221, indicating whether the threshold has been exceeded.

Output interface 222 may generate a signal 115 based on signal 221 and send it to external controller 120. Formatting signal 115 according to a specific protocol may include creating a message that contains the value of signal 221. While in this example, signal 221 is outputted to external controller 120 through output interface 222, it is also feasible for signal 221 to go directly to external controller 120.

An example of different implementations for signal 221 is provided. Signal 221 is generated based on the outcome of a comparison of a characteristic of signal 215 to a predetermined threshold. As noted above, the comparison may be performed by detector 220. When the threshold is surpassed by this characteristic, this indicates that a short circuit has occurred within the electrical system of which conductor 101 is part. Conversely, if the threshold is not exceeded, this indicates that no short circuit has been detected. In the present example, the characteristic compared to the threshold is the amplitude of signal 215. However, in alternative implementations, the characteristic may include the rate of change of amplitude over time or the summation of the amplitude over a particular time period.

In several implementations, signal 221 may be a binary signal: when signal 221 is set to ‘1’, this indicates that a short circuit has been detected, while a value of ‘0’ indicates that no short circuit has detected. Additionally or alternatively, signal 221 can be a digital signal that includes extra information about signal 215, such as its amplitude, rate of change, or any other relevant data. In some implementations, signal 221 may also encode an error code linked to the short circuit event, with the error code being present in signal 221 only when the threshold for the characteristic of signal 215 is exceeded.

Controller 230 may include a general-purpose processor, a special-purpose processor, digital logic, or any other suitable processing circuitry. Controller 230 may be configured to execute a control signal generator (hereinafter “generator 219). In the current example, generator 219 is implemented in hardware (e.g., using digital logic or other electronic circuitry). However, in alternative implementations, generator 219 could also be implemented in software or as a combination of hardware and software.

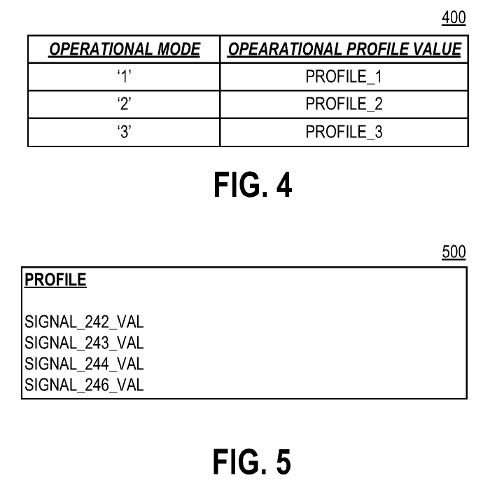

In one example, generator 219 may receive a user input and generate at least one of signals 242, 243, 244, and 246 based on the user input. The user input may specify an operational mode of sensor 110. In response to the user input, controller 230 may identify an operational profile of sensor 110 and set the value of at least one of signals 242, 243, 244, and 246 based on the identified operational profile. The operational profile may be identified by using a lookup table (or another data structure) that is stored in the memory (not shown) of controller 230. In some implementations, the operational profile may be identified based on a lookup table 400, which is shown in FIG. 4. As illustrated in FIG. 4, the lookup table may map each of a plurality of operational mode values to a different corresponding operational profile.

FIG. 5 illustrates an example of an operational profile 500, according to aspects of this disclosure. The operational profile 500 may be the same or similar to the profiles identified in lookup table 400. The profile 500 could be a data structure or a specific area in the memory of controller 230, and it may contain the respective values for each of signals 242-246. In this example, profile 500 provides a value for each of signals 242-246. However, in alternative implementations, profile 500 might specify the value of only one of the signals or fewer than all of them. Additionally, in some implementations, profile 500 might also indicate the value of at least one of signals 253 and 256.

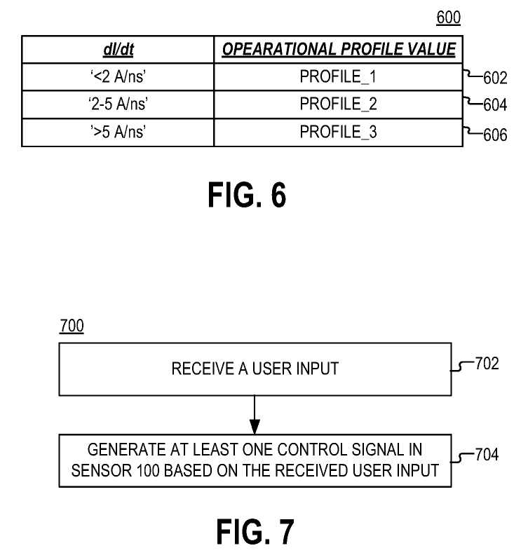

In another example, the user input that is provided to controller 230 may specify the rate at which the electrical current through conductor 101 is expected to change in the event of a short circuit occurring in the electric system of which conductor 101 is part. Based on this user input, controller 230 can retrieve the corresponding profile from memory, which specifies the values for at least one of signals 242 and 243. Subsequently, controller 230 may set signal 242 and/or signal 243 to the values defined in the retrieved profile. In some implementations, the profile may be identified using a lookup table 600, an example of which is shown in FIG. 6. This table may include entries 602, 604, and 606. Entry 602 maps a specific range for the current rate of change with the first profile, entry 604 maps a second range to a second profile, and entry 606 associates a third range with a third profile. In this example, the first range encompasses all values less than 2 A/ns, the second range includes values from 2 to 5 A/ns, and the third range consists of values greater than 5 A/ns. These ranges are provided as examples only; the disclosure is not limited to any specific range or set of ranges.

Each profile specified in lookup table 600 can define different values for signal 242 and/or different values for signal 243. In other words, each of the profiles may specify a different timing constant for rectifier 214 and/or circuit 114. When user input specifies a particular rate of change of current expected during a short circuit, controller 230 will search lookup table 600 to retrieve the profile that matches the user-specified value. For instance, if the user input indicates a value less than 2 A/ns, controller 230 may fetch the first profile (profile 1) from memory; if the input specifies a value in the 2-5 A/ns range, the second profile (profile 2) may be retrieved; and if the value exceeds 5 A/ns, the controller may access the third profile from memory.

According to the example of FIG. 6, lookup table 600 maps different current rate of change values to corresponding profile values. However, alternative implementations are possible in which table 600 maps each of a plurality of values for the maximum current that is expected to develop in conductor 101 in the event of a short circuit to a different corresponding profile. In such implementations, each of the profiles identified in lookup table 600 may specify one or more of: a different respective value for signal 244, a different respective value for signal 246, a different respective value for signal 253, and a different respective value for signal for signal 256. In other words each of the profiles may specify at least one of (i) which one of amplifier 218 and attenuator 216 would be turned on while the other is turned off, and (ii) the amount of attenuation and/or amplification that is applied to the output of sensing element 212 by the component that is turned on.

FIGS. 4 and 6 are provided as examples only. While a lookup table is utilized in these figures to relate user input to control signal values in sensor 110, alternative data structures may also be employed. The profiles mapped in the lookup table may be pre-stored in the memory of controller 230 during manufacturing. In this context, the term "user input" refers to data received at one or more inputs terminals of sensor 110 and/or controller 230. This input may originate from external controller 120 or another electronic device and can either be manually specified by an individual or automatically determined by external controller 120 or another electronic device.

FIG. 7 is a flowchart of an example of a process 700, according to aspects of the disclosure. According to the example of FIG. 7, process 700 is performed by controller 230. However, the present disclosure is not limited to any specific entity performing process 700. At step 702, controller 230 receives user input. In one example, the user input may specify the value of one or more of signals 242, 243, 244, 246, 253, and 256. In another example, the user input may specify the value of an operational parameter, such as the approximate (or maximum) rate of change at which the level of electrical current through conductor 101 would rise in the event of a short circuit, or the amplitude that would be reached by the electrical current through conductor 101. At step 704, controller 230 sets the values of one or more of control signals 242, 243, 244, 246, 253, and 256 based on the received input. For example, when the user specifies the value of one or more the signals, controller 230 may set those signals to the values that are being specified. As another example, when the user input specifies the value of an operational profile, the values of those signals may be identified based on a corresponding operational profile, as discussed above with respect to FIG. 6.

FIGS. 1-7 are provided as an example only. Throughout the disclosure, like reference numerals refer to like parts. The examples provided with respect to FIGS. 1-7 are not mutually exclusive and may be combined, modified, or adapted in various ways by those skilled in the art without departing from the scope and spirit of the invention defined by the appended claims. As used throughout the disclosure, the phrase “output of a sensing element” may refer to any signal that is at least in part generated by the sensing element. In the example of circuit 114, each of signals 213, 215, 221, and 114 is considered to be an output of sensing element 212. Moreover, the action of each of rectifier 214, 216, amplifier 218, and detector 220 may be regarded as an action on the output of sensing element 212. FIG. 3 provides an example of only one possible configuration of rectifier 214. It will be understood that the present disclosure is not limited to any specific configuration of rectifier 214.

The concepts and ideas described herein may be implemented, at least in part, via a computer program product, (e.g., in a non-transitory machine-readable storage medium such as, for example, a non-transitory computer-readable medium), for execution by, or to control the operation of, data processing apparatus (e.g., a programmable processor, a computer, or multiple computers). Each such program may be implemented in a high-level procedural or object-oriented programming language to work with the rest of the computer-based system. However, the programs may be implemented in assembly, machine language, or Hardware Description Language. The language may be a compiled or an interpreted language, and it may be deployed in any form, including as a stand-alone program or as a module, component, subroutine, or another unit suitable for use in a computing environment. A computer program may be deployed to be executed on one computer or multiple computers at one site or distributed across multiple sites and interconnected by a communication network. A computer program may be stored on a non-transitory machine-readable medium that is readable by a general or special purpose programmable computer for configuring and operating the computer when the non-transitory machine-readable medium is read by the computer to perform the processes described herein. For example, the processes described herein may also be implemented as a non-transitory machine-readable storage medium, configured with a computer program, where upon execution, instructions in the computer program cause the computer to operate in accordance with the processes. A non-transitory machine-readable medium may include but is not limited to a hard drive, compact disc, flash memory, non-volatile memory, or volatile memory. The term unit (e.g., a addition unit, a multiplication unit, etc.), as used throughout the disclosure may refer to hardware (e.g., an electronic circuit) that is configured to perform a function (e.g., addition or multiplication, etc.), software that is executed by at least one processor, and configured to perform the function, or a combination of hardware and software.

As used throughout the disclosure, the phrase “substantially equal” shall mean “within +/- 10% of being exactly equal”. As used throughout the disclosure, the phrase “substantially perpendicular” shall mean “within +/- 10 degrees of being exactly perpendicular”. As used throughout the disclosure, the phrase “substantially parallel” shall mean “within +/- 10 degrees of being exactly parallel”.

According to the present disclosure, a magnetic field sensing element can include one or more magnetic field sensing elements, such as Hall effect elements, magnetoresistance elements, or magnetoresistors, and can include one or more such elements of the same or different types. As is known, there are different types of Hall effect elements, for example, a planar Hall element, a vertical Hall element, and a Circular Vertical Hall (CVH) element. As is also known, there are different types of magnetoresistance elements, for example, a semiconductor magnetoresistance element such as Indium Antimonide (InSb), a giant magnetoresistance (GMR) element, for example, a spin valve, an anisotropic magnetoresistance element (AMR), a tunneling magnetoresistance (TMR) element, and a magnetic tunnel junction (MTJ). The magnetic field sensing element may be a single element or, alternatively, may include two or more magnetic field sensing elements arranged in various configurations, e.g., a half bridge or full (Wheatstone) bridge. Depending on the device type and other application requirements, the magnetic field sensing element may be a device made of a type IV semiconductor material such as Silicon (Si) or Germanium (Ge), or a type III-V semiconductor material like Gallium-Arsenide (GaAs) or an Indium compound, e.g., Indium-Antimonide (InSb).

Having described preferred embodiments, which serve to illustrate various concepts, structures and techniques, which are the subject of this patent, it will now become apparent that other embodiments incorporating these concepts, structures and techniques may be used. Accordingly, it is submitted that the scope of the patent should not be limited to the described embodiments but rather should be limited only by the spirit and scope of the following claims.

1. A current sensor, comprising:
a current sensing circuit that is configured to detect a level of electrical current through a conductor, the current sensing circuit including at least one first magnetic field sensing element and a processing circuitry, the sensing magnetic field sensing element being configured to generate a first signal in response to a magnetic field that is generated by the conductor as a result of electrical current flowing through the conductor, the processing circuitry being configured to generate a first output signal based on the first signal, the first output signal being indicative of a level of electrical current through the conductor; and
a short circuit sensing circuit that is configured to detect increases in the level of electrical current that is flowing through the conductor, the short circuit sensing circuit including at least one second magnetic field sensing element, a rectifier, and a detector, the second magnetic field sensing element being configured to generate a second signal in response to the magnetic field that is generated by the conductor as a result of electrical current flowing through the conductor, the rectifier being configured to rectify the second signal to produce a rectified signal, and the detector being configured to compare a characteristic of the rectified signal to a threshold and generate, at least in part, an output signal that is indicative of a presence of a short circuit when the characteristic of the rectified signal exceeds the threshold.

2. The current sensor of claim 1, wherein the characteristic of the rectified signal includes amplitude.

3. The current sensor of claim 1, wherein the characteristic of the rectified signal includes a rate of change of the rectified signal.

4. The current sensor of claim 1, wherein the short circuit sensing circuit further includes an attenuator that is configured to attenuate the rectified signal before the rectified signal is provided to the detector.

5. The current sensor of claim 1, wherein the short circuit sensing circuit further includes an attenuator that is configured to attenuate the first signal before the first signal is provided to the rectifier.

6. The current sensor of claim 1, further comprising a controller, the controller being configured to receive a user input and set a timing constant of the rectifier based on the user input.

7. The current sensor of claim 1, wherein the detector includes a comparator that is configured to compare an amplitude of the of the rectified signal to the threshold.

8. The current sensor of claim 1, wherein the detector includes an integrator that is configured to integrate the rectified signal over a predetermined time period to generate an integrated signal, and compare the integrated signal to the threshold.

9. The sensor of claim 1, wherein the second magnetic field sensing element includes an inductive coil.

10. The sensor of claim 1, wherein the short circuit sensing circuit further includes an amplifier that is configured to amplify the rectified signal before the rectified signal is provided to the detector.

11. A current sensor, comprising:
a current sensing circuit that is configured to detect a level of electrical current through a conductor, the current sensing circuit including at least one first magnetic field sensing element and a processing circuitry, the first magnetic field sensing element being configured to generate a first signal in response to a magnetic field that is generated by the conductor as a result of electrical current flowing through the conductor, the processing circuitry being configured to generate a first output signal based on the first signal, the first output signal being indicative of a level of electrical current through the conductor; and
a short circuit sensing circuit that is configured to detect increases in the level of electrical current that is flowing through the conductor, the short circuit sensing circuit including at least one second magnetic field sensing element, an attenuator, and a detector, the second magnetic field sensing element being configured to generate a second signal in response to the magnetic field that is generated by the conductor as a result of electrical current flowing through the conductor, the attenuator being configured to attenuate the second signal before the second signal is provided to the detector, and the detector being configured to compare a characteristic of the second signal to a threshold and generate, at least in part, an output signal that is indicative of a presence of a short circuit when the characteristic of the second signal exceeds the threshold.

12. The current sensor of claim 11, wherein the short circuit sensing circuit further includes a rectifier that is configured to rectify the second signal to produce a rectified signal, and provide the rectified signal to the detector, wherein providing the second signal to the detector includes providing the rectified signal to the detector.

13. The current sensor of claim 12, wherein the detector includes a comparator that is configured to compare an amplitude of the of the rectified signal to the threshold.

14. The current sensor of claim 12, wherein the detector includes an integrator that is configured to integrate the rectified signal over a predetermined time period to generate an integrated signal, and compare the integrated signal to the threshold.

15. The current sensor of claim 11, further comprising a controller, the controller being configured to receive a user input and set an attenuation level of the attenuator based on the user input.

16. The current sensor of claim 11, wherein the second magnetic field sensing element includes an inductive coil.

17. A current sensor, comprising:
a current sensing circuit that is configured to detect a level of electrical current through a conductor, the current sensing circuit including at least one first magnetic field sensing element and a processing circuitry, the first magnetic field sensing element being configured to generate a first signal in response to a magnetic field that is generated by the conductor as a result of electrical current flowing through the conductor, the processing circuitry being configured to generate a first output signal based on the first signal, the first output signal being indicative of a level of electrical current through the conductor; and
a short circuit sensing circuit that is configured to detect increases in the level of electrical current that is flowing through the conductor, the short circuit sensing circuit including at least one second magnetic field sensing element, a rectifier, and a detector, the second magnetic field sensing element being configured to generate a second signal in response to the magnetic field that is generated by the conductor as a result of electrical current flowing through the conductor, the rectifier being configured to rectify the second signal to produce a rectified signal, and the detector being configured to integrate the rectified signal over a predetermined time period to produce an integrated signal, compare the integrated signal to a threshold, and generate, at least in part, an output signal that is indicative of a presence of a short circuit when the integrated signal exceeds the threshold.

18. The current sensor of claim 17, wherein the short circuit sensing circuit further includes an attenuator that is configured to attenuate the rectified signal before the rectified signal is provided to the detector.

19. The current sensor of claim 17, wherein the short circuit sensing circuit further includes an attenuator that is configured to attenuate the first signal before the first signal is provided to the rectifier.

20. The current sensor of claim 17, further comprising a controller, the controller being configured to receive a user input and set a timing constant of the rectifier based on the user input.
